(19) United States
(12) Patent Application Publication
(10) Pub. No.: US 2008/0318153 A1
(43) Pub. Date: Dec. 25, 2008

(54) PHOTOSENSITIVE LAYER STACK

(75) Inventor: Rainer Pforr, Dresden (DE)

Correspondence Address: EDELL, SHAPIRO & FINNAN, LLC, 1901 RESEARCH BLVD., SUITE 400, ROCKVILLE, MD, 20850, US

(73) Assignee: Qimonda AG, Munich (DE)

(21) Appl. No.: 11/765,342

(22) Filed: Jun. 19, 2007

(51) Int. Cl. G03F 7/004; G03F 7/20; G03B 27/42

(52) U.S. Cl. 430/270.1; 430/322; 355/53

(57) ABSTRACT

A photosensitive layer stack and methods for multiple exposure lithography are disclosed having a bleachable layer with a first absorption switching from absorptive to transmissive upon irradiation and a photochromic layer having a second absorption switching from transmissive to absorptive upon irradiation.

### BACKGROUND OF THE INVENTION

A photosensitive layer stack, method, and system are described with respect to improving dimensional resolution by pitch fragmentation during lithographic projection of a layer of an integrated circuit.

### SUMMARY OF THE INVENTION

A photosensitive layer stack and methods for multiple exposure lithography are disclosed having a bleachable layer with a first absorption switching from absorptive to transmissive upon irradiation and a photochromic layer having a second absorption switching from transmissive to absorptive upon irradiation.

### BRIEF DESCRIPTION OF THE DRAWINGS

FIGS. 1A, 1B, and 1C illustrate a photosensitive layer stack according to embodiments of the invention.

FIGS. 2 to 8 illustrate a photosensitive layer stack in various stages of processing according to an embodiment of the invention;

FIGS. 8 to 11 illustrate a photosensitive layer stack in various stages of processing according to a further embodiment of the invention;

FIGS. 12 to 17 illustrate a photosensitive layer stack in various stages of processing according to a further embodiment of the invention;

FIGS. 18 and 19 each illustrate a flow chart of method steps according to an embodiment of the invention.

FIG. 20 illustrates a lithographic system according to an embodiment of the invention.

Like reference numerals have been used to identify like elements throughout this disclosure.

### DETAILED DESCRIPTION OF THE INVENTION

Embodiments of photosensitive layer stack for multiple exposure lithography, method and system for multiple exposure lithography are discussed in detail below. It is appreciated, however, that the present invention provides many applicable inventive concepts that can be embodied in a wide variety of specific contexts. The specific embodiments discussed are merely illustrative of specific ways and do not limit the scope of the invention.

In the following, embodiments of the photosensitive layer stack, method, and system are described with respect to improving dimensional resolution by pitch fragmentation during lithographic projection of a layer of an integrated circuit. The embodiments, however, might also be useful in other respects, e.g., pattern fidelity of two-dimensional structures or manufacturability of a layer of an integrated circuit.

Furthermore, it should be noted that the embodiments are described with respect to line-space-patterns, but might also be useful in other respects, including but not limited to dense patterns, semi dense patterns, patterns with isolated lines or two-dimensional patterns, and combinations between all them. Lithographic projection can also be applied during manufacturing of different products, e.g. semiconductor circuits and thin film elements. Other products, e.g., liquid crystal panels or the like might be produced as well.

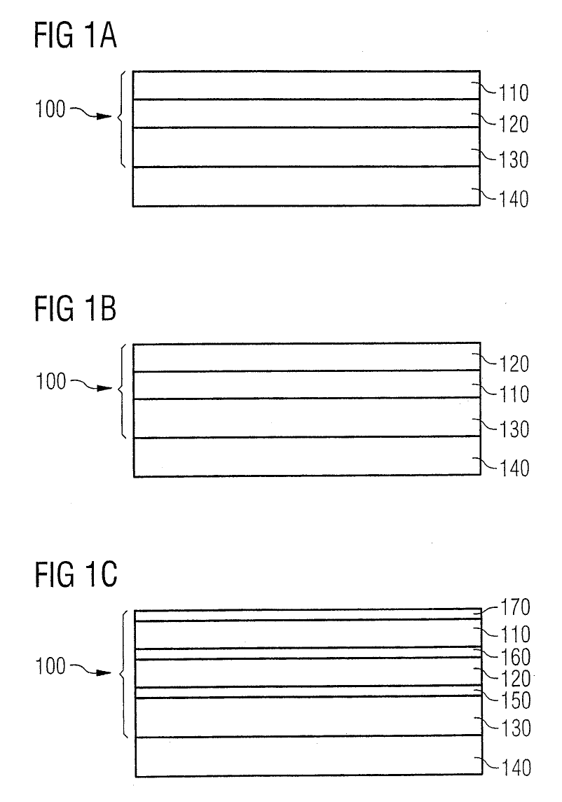

In FIG. 1A, a first embodiment of a photosensitive layer stack is shown. The photosensitive layer stack 100 includes a photochromic layer 110 and a bleachable layer 120. As shown in FIG. 1A, the bleachable layer 120 is arranged below the photochromic layer 110. Below the bleachable layer, a structuring or resist film layer 130 is arranged on a substrate 140. By way of example, the structuring layer 130 may be a resist film layer suitable for structuring under actinic light having a wavelength of about 193 nm.

It should be noted that the term “photochromic” refers to an absorption property of layer 110 where the absorption changes from initially transmissive to absorptive under irradiation. This behavior is known as photochromic effect. Suitable materials will be discussed below. The photochromic layer 110 can be based on a reversible or irreversible photochromic effect.

Utilizing the reversible photochromic effect, an absorption change from initially transmissive to absorptive is followed by a return to the transparent state after a certain time.

In case of irreversible photochromic effect, the photochromic layer 110 remains in the absorptive state. In addition, any intermediate behavior including, for example, a partial absorption without fully recovering into the initial transmissive state is considered to be within the scope of the term “photochromic.”

In the following, the term “bleachable” refers to an absorption property of layer 120 where the absorption changes from initially absorptive to transmissive under irradiation. Suitable materials will be discussed below.

When describing embodiments related to photolithographic structuring, any kind of lithographic projection apparatus using a wide spectrum of different feasible illumination wavelength can be used. Within the described embodiments, a projective optical system using a UV light source of about 193 nm may be employed having a certain demagnification. Other wavelengths, however, may be utilized (e.g., wavelengths of about 248 nm or about 158 nm). Furthermore, lithographic projection means with various projection systems may be used, such as proximity projection, reflective projection, etc. In addition, high NA systems like immersion lithography systems may be employed.

The term “substrate” includes semiconductor wafers having an already structured layer or already structured layer systems being arranged partially or fully covering the substrate. Silicon, germanium or gallium arsenide either doped or undoped are suitable materials. However, other materials of semiconductor wafers are not excluded. Furthermore other substrates like glass, plastic, or the like are also within the scope of term “substrate”.

FIG. 1B illustrates photosensitive stack layer in accordance with another embodiment of the invention. As shown, the photosensitive layer stack 100 may include the photochromic layer 110 and the bleachable layer 120, with the bleachable layer 120 arranged above the photochromic layer 110. In addition, the photochromic layer 110 is arranged above the structuring layer 130 on the substrate 140.

It should be noted that in the embodiments depicted in FIG. 1A and FIG. 1B (and also in the following embodiments), the structuring layer 130 may be either a positive or negative type resist, for example.

In the photosensitive layer stack 100, the bleachable layer 120 switches from absorptive to transmissive under irradiation with electromagnetic radiation. The electromagnetic radiation can be provided by an exposure device having, e.g., a wavelength in the UV-range (e.g. about 193 nm). Once a first irradiation dose has been reached, the bleachable layer 120 switches from absorptive to transmissive.

A suitable material for bleachable layer 120 includes composites having bleachable characteristics under UV-radiation. By way of example, the bleachable layer may include composites such as Dinitrophenol, Nitrosalicylaldene, m-Nitrophenol, or Ethylorange. It is also possible to use nano-sized particles formed from copper, silicon, germanium, and their various isomers, alloys or oxides.

In general, absorption of the photochromic layer 110 switches from transmissive to absorptive after a specific treatment.

In a first example, a further irradiation can be performed with a wavelength being different to the wavelength of the first irradiation. For example, the first irradiation can use an exposure with electromagnetic radiation having a wavelength of below about 250 nm. Subsequently, a second irradiation uses exposure with electromagnetic radiation having a wavelength higher than that of the first irradiation, e.g., above about 250 nm. Accordingly, the resist film layer 130 can be selected such that it is only sensitive to the first irradiation and not the second irradiation. In general, the absorption conditions of the photosensitive layer stack 100 are adapted to the exposure characteristics of an appropriate resist film material for the resist film layer 130, i.e., by taking into account exposure dose threshold and sensitivity range.

The treatment can also include affecting the photochromic layer 110 with a gas or a liquid, performing a wait cycle for a predetermined time following the first irradiation, or performing a thermal cycle, i.e., by heating the layer stack 100 with an appropriate thermal source such as an infrared source, for example.

Furthermore, this treatment can be an irradiation with the same electromagnetic radiation that alters the properties of bleachable layer 120. It should be noted, however, that a second irradiation dose, which can be different to the first irradiation dose of bleachable layer 120, might be necessary. For example, the second irradiation dose can be larger than the first irradiation dose. In this case, photochromic layer 110 shows a saturation behavior, i.e., the absorption reaches the absorptive state after exposure with the second irradiation dose has been performed.

The photochromic layer 110 may include composites having photochromic characteristics. By way of example, the photochromic layer 110 may include compounds such as Vulgin, Spiroxazine, and Chrome. It is also possible to use nano-sized particles formed from copper, silicon, germanium, and their various isomers, alloys or oxides.

A further embodiment is shown with respect to FIG. 1C. As shown in FIG. 1C, a first interface layer 150 can be arranged below the bleachable layer 120. A second interface layer 160 can be arranged between the bleachable layer 120 and the photochromic layer 110. A third interface layer 170 can be arranged above the photochromic layer 110. The first interface layer 150, the second interface layer 160, and the third interface layer 170 each serve as a barrier between the respective pairs of photochromic layer 110, bleachable layer 120, and structuring layer 130 in order to allow for unaltered optical behavior during deposition of photochromic layer 110, bleachable layer 120, and structuring layer 130, as well as for the improved adhesion of the individual layers of layer stack 100 or anti-reflective coating. Furthermore, the first interface layer 150, the second interface layer 160, and the third interface layer 170 can serve as a chemical barrier such that the individual characteristics of the individual layers of the layer stack 100 remain constant after deposition.

In general, the photosensitive layer stack 100 with or without the first interface layer 150, the second interface layer 160, and the third interface layer 170 can include composites being soluble in a solvent such as water or a resist developer solution. However, when employing immersion lithography, photochromic layer 110 and/or bleachable layer 120 can include composites being not soluble in water in order to serve as a top coating for immersion lithography.

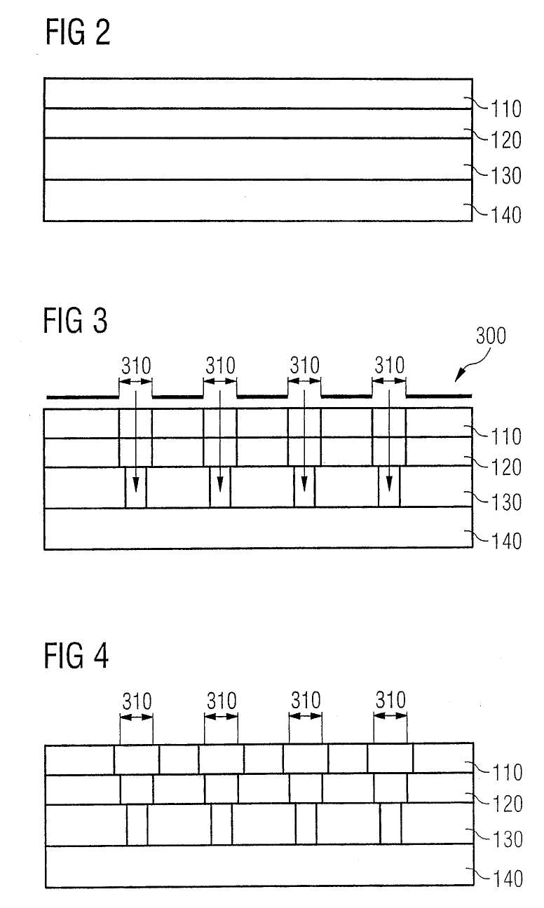

In the following, the embodiment according to FIG. 1A is now explained in more detail when performing multiple exposures in an exposure tool. Referring to FIG. 2, the semiconductor wafer or substrate 140 is provided having the resist film layer 130, the bleachable layer 120, and the photochromic layer 110 deposited on its surface, e.g., by spin coating or any other suitable deposition technique. It should be noted that the embodiments according to FIG. 1B or 1C can also serve as a starting point for further processing steps. The coated substrate is placed within an exposure apparatus, e.g., by depositing the coated substrate on a substrate holder. Other processing steps, like alignment procedures, may be necessary to provide full functionality.

In the next step, as depicted in FIG. 3, a first exposure is performed. During the first exposure, a first pattern is projected onto the substrate 140. The first pattern is provided on a structuring device, which can be a photomask of any type (e.g., chrome-on-glass, attenuating phase shift, or the like). For simplicity, FIG. 3 only depicts the corresponding first pattern 300 when projected onto the substrate 140. A projection optic is usually provided in order to project the first pattern of the structuring device onto the substrate 140 including a demagnification of 4 to 5, for example.

During the first exposure, the photochromic layer 110 is irradiated by UV-photons in first areas 310 that are not blocked by absorbing elements of the first pattern on corresponding parts of the photomask. As a consequence, the photochromic layer 110 switches from transmissive to absorptive irradiating in the first area 310. As long as the photochromic layer 110 is still transmissive, UV-photons also illuminate the bleachable layer 120, which, in turn, switches the absorption from initially absorptive to transmissive. During the transmissive state of the bleachable layer 120, UV-photons irradiate the resist film layer 130 in a first area 310 corresponding to the first pattern.

The above described absorption changes of photochromic layer 110 and bleachable layer 120 are related to the respective irradiation dose. As explained above, the bleachable layer 120 can switch from absorptive to transmissive once a first irradiation dose has been reached. Absorption of the photochromic layer 110 can switch from transmissive to absorptive after a specific treatment, e.g., applying the irradiation which also exposes the bleachable layer 120 and structuring layer 130. After reaching a second irradiation dose, which can be larger than the first irradiation dose of bleachable layer 120, the absorption of the photochromic layer 110 changes after the bleachable layer has already turned its state into transmissive, allowing the resist film to become exposed in first areas 310.

The treatment can also include affecting the photochromic layer 110 with a gas or a liquid, performing a wait cycle for a predetermined time following irradiation, performing a thermal cycle, i.e., by heating the layer stack 100 with (e.g., an infrared source), or performing a further irradiation with a different wavelength, as explained above.

After treatment of the photochromic layer 110 has been performed, the resulting layer structure on substrate 140 is depicted in FIG. 4. The structuring layer 130 is exposed in areas 310 below corresponding transmissive areas on bleachable layer 120 and corresponding absorptive areas on the photochromic layer 110. Please note that the treatment of the photochromic layer 110 can also affect the dimensions of the corresponding absorptive areas on photochromic layer 110. As an example, the corresponding absorptive areas on photochromic layer 110 can be increased with respect to the first area 310, as depicted in FIG. 4. It is, however, also conceivable to provide a reduced corresponding absorptive areas on photochromic layer 110.

After completion of the first exposure with the first pattern, a second exposure using a second pattern is performed. Both first and second pattern can be an alternating line space pattern having the corresponding lines in spaces of the other pattern. When overlaying the first and second pattern, i.e., by performing a multiple exposure, the resulting structure has a finer pitch as compared to the structures of first and second pattern, thus resulting in finer lithographic structures by pitch fragmentation.

The first pattern and the second pattern can be arranged on different areas of a single photomask. It is, however, also conceivable that the first pattern is arranged on a first photomask and the second pattern is arranged on a second photomask. The first photomask can be replaced by the second photomask after performing the first exposure. It should be noted that substrate 140 still remains within the lithographic apparatus. Accordingly, no additional alignment or adjustment steps are necessary for substrate 140. It should be mentioned that usually the mask alignment necessary for exchanging between first and second pattern can be performed with a much higher accuracy as compared to a wafer stage alignment.

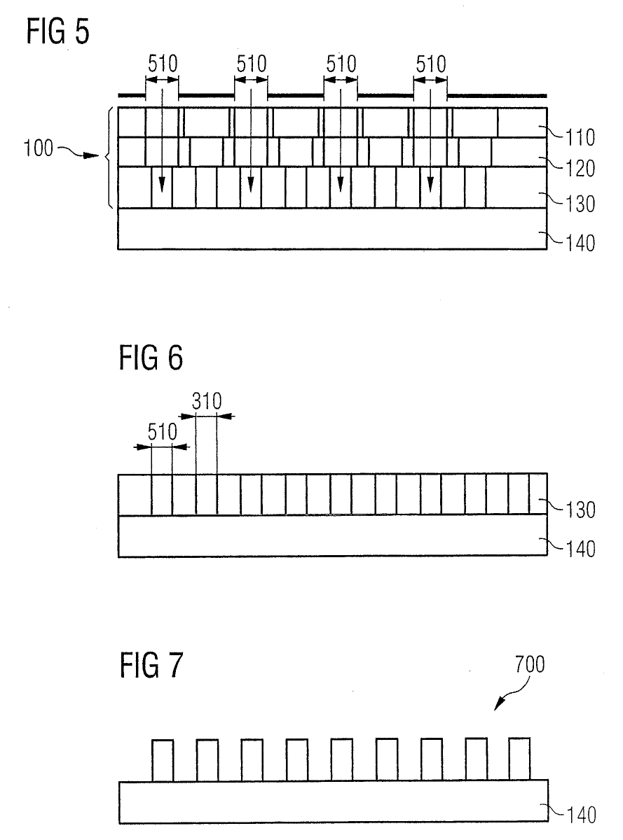

Referring to FIG. 5, the second exposure irradiates the photochromic layer 110 in corresponding second areas 510 that are arranged between previously irradiated first areas 310. Accordingly, the photochromic layer 110 is transmissive outside the first areas 310, as no further treatment has been performed in the recent step. After irradiating the bleachable layer 120, the bleachable layer 120 switches from absorptive to transmissive. Following this, the resist film layer 130 is exposed in the second area 510 corresponding to the second pattern.

It should be noted that, according to this embodiment, during the second exposure, no further treatment of photochromic layer 110 is necessary. Below a further embodiment is described wherein the photochromic layer 110 also undergoes a absorption change similar to the first exposure step.

During second exposure, no actinic light under higher diffraction orders or actinic light being scattered at the photomask or stray light can enter the already exposed first areas 310 corresponding to the first pattern. This is due to the fact that the photochromic layer 110 is absorptive in the first areas 310 (or even in an extended area, as described above), so as to serve as a light shield during the second exposure. This greatly improves pattern fidelity, as no unwanted exposure of the resist film layer 130 can take place.

Processing continues by removing the photochromic layer 110 and the bleachable layer 120, as shown in FIG. 6. This can be performed either in a single step or in different steps, or by employing intermediate processing steps for enabling the removal of the photochromic layer 110 and the bleachable layer 120. In addition, a post-exposure-bake can be performed so as to stabilize the structuring layer 130.

As shown in FIG. 7, a development process of the resist film layer 130 can be performed. The resulting resist structure 700 is then used for structuring an underlying layer in substrate 140 or as a mask for an implantation step or for any other process sequence which might be necessary for further processing the substrate 140.

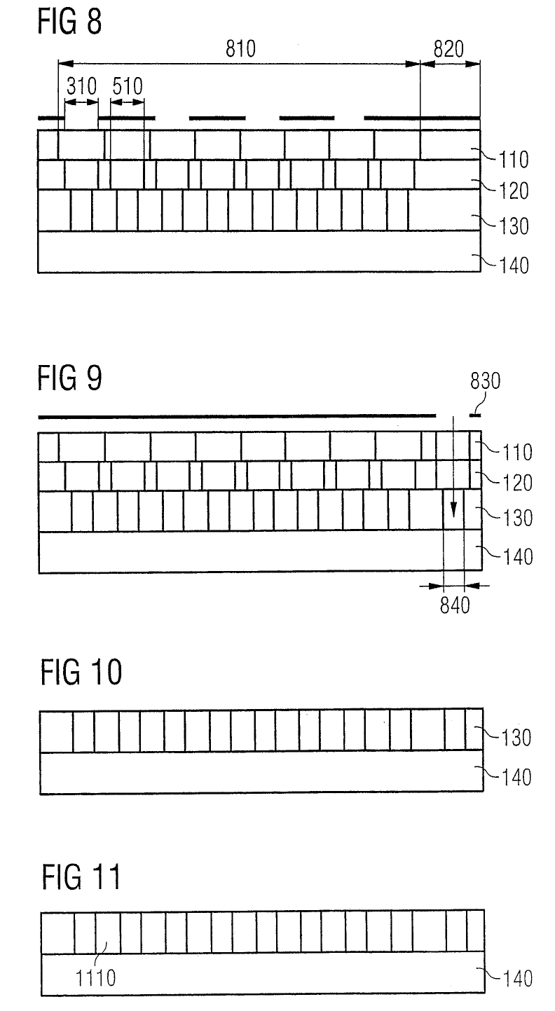

A further embodiment is now described with respect to FIGS. 8 to 11. The processing sequence starts after the second exposure has been performed, i.e., as depicted in FIG. 5 of the previous embodiment. As shown in FIG. 8, after the second exposure, a further treatment of photochromic layer 110 is performed so as to alter its absorption from transmissive to absorptive in a region which includes both the first areas 310 and the second areas 510. Suitable processing steps are similar as already explained with respect to the first exposure step, i.e., performing a further irradiation, a thermal cycle, a wait cycle or a chemical interaction with a gas or a liquid.

Referring to FIG. 8, the photochromic layer 110 becomes, after the treatment, absorptive in a region 810, which includes the first area 310 and the second area 510 where previously an exposure has been performed. The treatment changes the photochromic layer 110 into its absorptive state only in those parts which have previously been exposed. It should be noted that due to the widening of first area 310 and second area 510 during treatment of photochromic layer 110, the region 810 can be a single area (shown in FIG. 8). It is, however, also possible that between the first area 310 and the second area 510, parts of the photochromic layer 110 still remain transmissive. In general, the outer area 820 of the photochromic layer 110 outside the exposed region 810 is still active in a sense that there the photochromic layer 110 is transmissive.

This fact can now be exploited to perform a third exposure outside the previously exposed region 810. It should be noted that a layout pattern used in manufacturing of different kinds of memory circuits (for example. DRAMs, FeRAM, NROM or the like) include a so-called cell array, which is located at the position of the individual memory cells. The cell array consists of very dense individual elements in order to arrive at high density memory cells. The cell array is surrounded by periphery structures which are used to select certain memory cells during operation of the memory chip. While the cell array consist of a regular pattern, the periphery structures quite often are represented by different patterns having line elements both in vertical and horizontal directions.

For lithographic projection, the imaging conditions can not usually be simultaneously optimized so as to precisely image the cell array and the periphery structures. According to this embodiment, the cell array can be printed in high resolution due to pitch fragmentation during the first and second exposure steps, while the periphery structures are transferred into resist film layer 130 during the third exposure.

Furthermore, it is possible to select the imaging conditions differently for each of the first and second exposure, as well as for the third exposure such that a pattern transfer form structuring device to the substrate can be achieved with a large process window and improved pattern fidelity as compared to a projection where a compromise between the cell array and the periphery structures has to be chosen. For example, the first and second exposure steps can be performed with polarized off-axis illumination and the third exposure can be performed with unpolarized on-axis illumination.

The projection of the third pattern is schematically shown in FIG. 9 by a corresponding pattern 830, which is transferred in a third area 840 into the resist film layer 130. Again, no actinic light under higher diffraction orders or actinic light being scattered at the photomask or stray light can enter the already exposed first areas 310 corresponding to the first pattern and the already exposed second areas 510 corresponding to the second pattern due to the fact that the photochromic layer 110 is absorptive in the exposed region 810 and serves as a light shield during the third exposure. Consequently, no unwanted or unintended exposure of the resist film layer 130 can take place.

Processing continues by removing the photochromic layer 110 and the bleachable layer 120, as shown in FIG. 10. This can be performed either in a single step or in different steps or employing intermediate processing steps for enabling the removal of the photochromic layer 110 and the bleachable layer 120. In addition, a post-exposure-bake can be performed so as to stabilize the resist film layer 130.

As shown in FIG. 11, a development process of the resist film layer 130 can be performed. The resulting resist structure 1110 is then used for structuring an underlying layer in substrate 140, or as a mask for an implantation step or for any other process sequence which might be necessary for further processing the substrate 140.

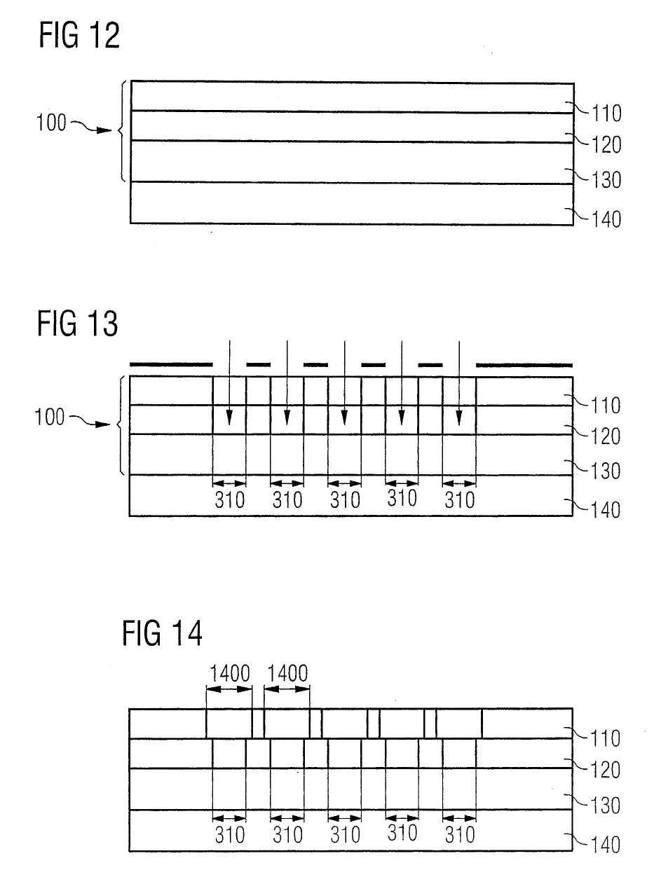

A further embodiment is now described with reference to FIGS. 12 to 17. This embodiment further exploits absorption characteristics of the photosensitive layer stack 100 in order to provide a contact mask, i.e., a mask pattern being arranged above the resist film 130 as will become apparent below. Referring to FIG. 12, the semiconductor wafer or substrate 140 is provided, the wafer 140 including the resist film layer 130, the bleachable layer 120, and the photochromic layer 110 deposited on its surface. The coated substrate is inserted into an exposure apparatus.

In the next step, as depicted in FIG. 13, a first exposure is performed. During the first exposure, the first pattern is projected on the photochromic layer 110. The first pattern is provided on the structuring device, e.g., the photomask. During the first exposure the photochromic layer 110 is irradiated by UV-photons in first areas 310 which are not blocked by absorbing elements of the first pattern on corresponding parts of the photomask. As a consequence, the photochromic layer 110 switches from transmissive to absorptive irradiating in the first area 310. As long as the photochromic layer 110 is still transmissive, UV-photons also illuminate the bleachable layer 120, which still remains in its initially absorptive state. When comparing the behavior of photochromic layer 110 and bleachable layer 120 to the above described embodiments, it should be noted that, in accordance with the embodiment of FIG. 13, the sensitivities under actinic light are different. Here, the bleachable layer 120 is not turned into its transmissive state during the first exposure so as to not expose the resist film layer 130.

During the first exposure, UV-photons do not irradiate the resist film layer 130 in the first area 310 as UV-photons are absorbed within the bleachable layer 120. It should be noted that “absorbed” means that the resist film layer 130 does not be exposed above its exposure dose threshold or well below the exposure dose threshold. Blocking of substantially all UV-photons is not required although possible and within the scope of the term “absorbed”.

Absorption of the photochromic layer 110 can switch from transmissive to absorptive after a specific treatment, which includes affecting the photochromic layer 110 with a gas or a liquid, performing a wait cycle for a predetermined time following irradiation, performing a thermal cycle, i.e. by heating the layer stack 100 with e.g. an infrared source, or performing a further irradiation with a different wavelength, as explained above. The treatment of photochromic layer 110 can also affect the dimensions of the corresponding absorptive areas on photochromic layer 110. As shown in FIG. 14, the corresponding absorptive areas 1400 on photochromic layer 110 are increased with respect to the first area 310. It is, however, conceivable to also provide reduced corresponding absorptive areas on photo chromatic layer 110, especially when using a negative resist.

After treatment of photochromic layer 110 has been performed, the resulting layer structure on substrate 140 is depicted in FIG. 14. As explained above, the bleachable layer 120 is still absorptive as the specific first irradiation dose has been reached, thus leaving the photo resist 130 unexposed in areas 310 below corresponding absorptive areas on photochromic layer 110.

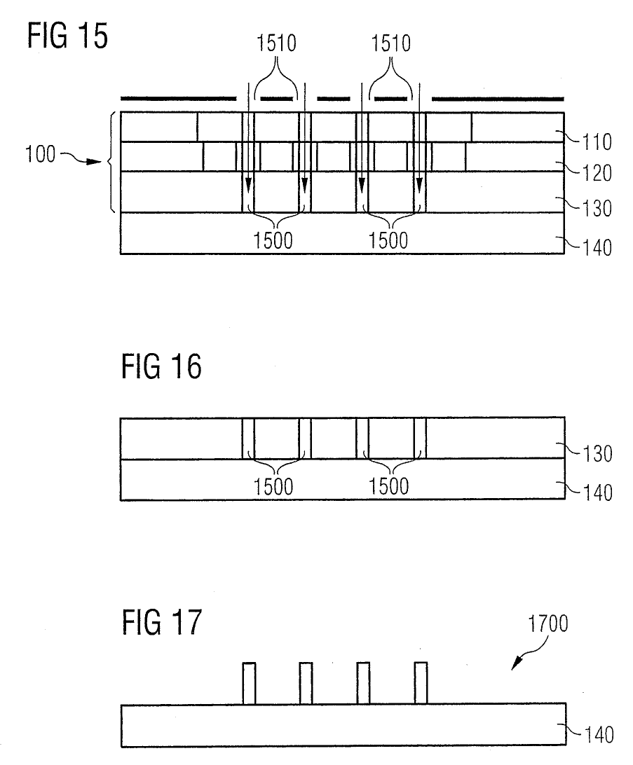

With respect to FIG. 15, a second exposure step is shown, which irradiates through the remaining transmissive portions of photochromic layer 110 into the bleachable layer 120. As a result, the bleachable layer 120 switches from absorptive to transmissive, irradiating the resist film layer in a second area 1500 as defined by the transmissive portions of photochromic layer 110. The second exposure can either utilize a further photomask with a further pattern 1510 (as depicted in FIG. 15) or a flood exposure without using a structuring device. When using a further pattern 1510, the first exposure can be used to print cell array structures and the second exposure can be used to print periphery structures, as explained above.

Processing continues by removing the photochromic layer 110 and the bleachable layer 120, as shown in FIG. 16. This can be performed either in a single step or in different steps or employing intermediate processing steps for enabling the removal of the photochromic layer 110 and the bleachable layer 120. In addition, a post-exposure-bake can be performed so as to stabilize the resist film layer 130.

As shown in FIG. 17, a development process of the resist film layer 130 can be performed. The resulting resist structure 1700 is then used for structuring an underlying layer in substrate 140 or as mask for an implantation step or for any other process sequence which might be necessary for further processing the substrate 140.

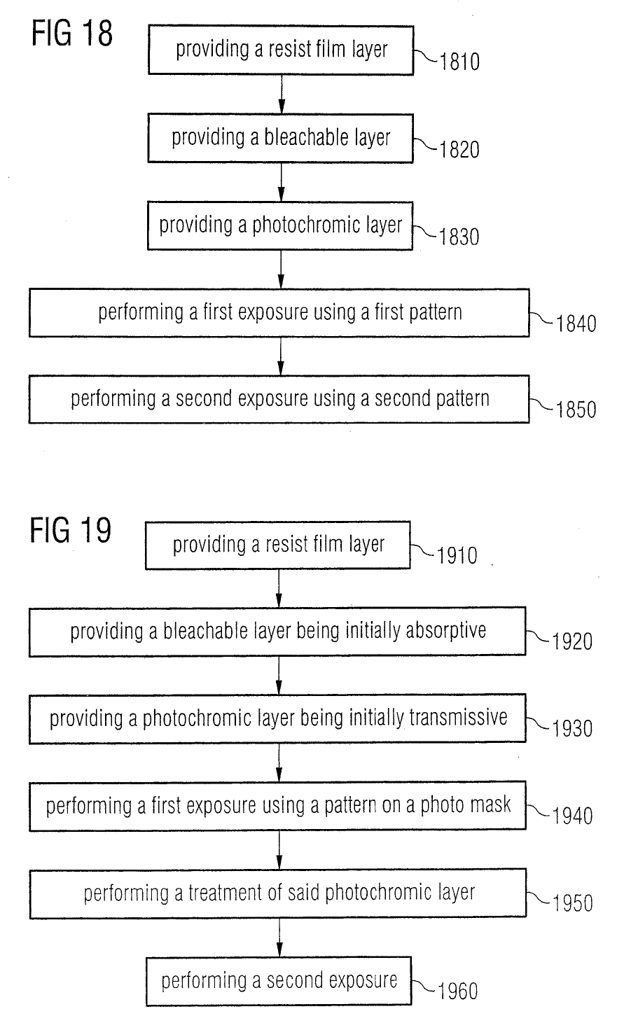

In FIG. 18, method steps for multiple exposure lithography are depicted in a flow diagram. In step 1810, a resist film layer is provided. In step 1820, a bleachable layer is provided and, in step 1830, a photochromic layer is provided. In step 1840, a first exposure using a first pattern is performed, which irradiates the photochromic layer such that it switches from transmissive to absorptive, the bleachable layer such that it switches the absorption from initially absorptive to transmissive, and irradiating the resist film layer in a first area corresponding to the first pattern.

In step 1850, a second exposure using a second pattern is performed, which irradiates the photochromic layer such that it switches from transmissive to absorptive, the bleachable such that it switches from absorptive to transmissive, and the resist film layer in a second area corresponding to the second pattern.

In FIG. 19, method steps for multiple exposure lithography are depicted in a flow diagram. In step 1910, a resist film layer is provided. In step 1920, a bleachable layer being initially absorptive is provided and in step 1930, a photochromic layer being initially transmissive is provided.

In step 1940, a first exposure using a pattern on a photomask is performed, which irradiates the photochromic layer in a first area. In step 1950, a treatment of the photochromic layer is performed so as to switch the photochromic layer from transmissive to absorptive at least in the first area. Afterwards, in step 1960, a second exposure is performed, which irradiates the bleachable layer so as to switching from absorptive to transmissive and the resist film layer in a second area.

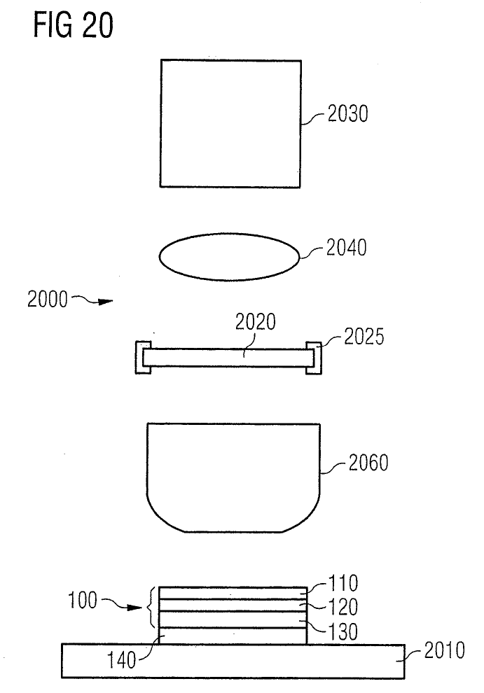

In FIG. 20, a lithographic system for multiple exposure lithography is depicted including a lithographic projection apparatus 2000 with a substrate holder 2010 and a photomask 2020 attached to a mask holder 2025. The substrate 140 is arranged on the substrate holder 2010 and includes the layer stack 100 with the bleachable layer 120 deposited on the resist film 130 and the photochromic layer 110.

The projection apparatus 2000 furthermore includes a light source 2030, which is, e.g., an excimer laser with 193 nm wavelength. An illumination optic 2040 projects the light coming from the light source 2030 through the photomask 2020 into an entrance pupil of a projection system 2060. The photomask 2020 can include the first pattern and the second pattern, which can be arranged on different areas of a single photomask. It is, however, also conceivable that the first pattern is arranged on a first photomask and the second pattern is arranged on a second photomask. The first photomask can be replaced by the second photomask after performing the first exposure.

Accordingly, the substrate 140 remains within the lithographic apparatus. Consequently, no additional alignment or adjustment steps are necessary for the substrate 140. It should be mentioned that mask alignment in mask holder 2025 necessary for exchanging between first and second pattern can be performed with a much higher accuracy as compared to a wafer stage alignment in substrate holder 2010.

Having described embodiments of the invention, it is noted that modifications and variations can be made by persons skilled in the art in light of the above teachings. It is therefore to be understood that changes may be made in the particular embodiments of the invention disclosed which are within the scope and spirit of the invention as defined by the appended claims.

I claim:

1. A photosensitive layer stack for multiple exposure lithography comprising:
a bleachable layer having a first absorption at which the bleachable layer switches from absorptive to transmissive upon irradiation; and
a photochromic layer with a second absorption at which the photochromic layer switches from transmissive to absorptive upon irradiation.

2. The photosensitive layer stack according to claim 1, wherein the photochromic layer is arranged above the bleachable layer.

3. The photosensitive layer stack according to claim 1, wherein the photochromic layer is arranged below the bleachable layer.

4. The photosensitive layer stack according to claim 1, wherein the first absorption of the bleachable layer switches from absorptive to transmissive when irradiated with electromagnetic radiation having a wavelength in the UV-range above a first irradiation dose.

5. The photosensitive layer stack according to claim 1, wherein the second absorption of the photochromic layer switches from transmissive to absorptive after a further treatment.

6. The photosensitive layer stack according to claim 5, wherein the further treatment comprises irradiation with electromagnetic radiation having a wavelength in the UV-range above a second irradiation dose.

7. The photosensitive layer stack according to claim 6, wherein the first irradiation dose is less than the second irradiation dose.

8. The photosensitive layer stack according to claim 5, wherein the further treatment comprises affecting the photochromic layer with a gas or a liquid.

9. The photosensitive layer stack according to claim 5, wherein the further treatment comprises performing a wait cycle for a predetermined time following irradiation.

10. The photosensitive layer stack according to claim 6, wherein the further treatment comprises performing a further irradiation having a wavelength different than the wavelength of the irradiation with electromagnetic radiation.

11. The photosensitive layer stack according to claim 10, wherein the irradiation comprises exposure with electromagnetic radiation having a wavelength below 250 nm and the further irradiation comprises exposure with electromagnetic radiation having a wavelength above 250 nm.

12. The photosensitive layer stack according to claim 5, wherein the further treatment comprises performing a thermal cycle.

13. The photosensitive layer stack according to claim 1 further comprising a structuring layer, the structuring layer being arranged below the bleachable layer or the photochromic layer.

14. The photosensitive layer stack according to claim 13, wherein the structuring layer comprises a positive or negative photoresist layer.

15. The photosensitive layer stack according to claim 1, wherein the photochromic layer and the bleachable layer include composites being soluble in a solvent.

16. The photosensitive layer stack according to claim 15, wherein the solvent is selected form the group consisting of water and a resist developer solution.

17. The photosensitive layer stack according to claim 1, wherein:
the photochromic layer and the bleachable layer include water insoluble composites; and
the photochromic layer is a top coating for immersion lithography.

18. The photosensitive layer stack according to claim 2 further comprising a first interface layer arranged below the bleachable layer.

19. The photosensitive layer stack according to claim 18 further comprising a second interface layer being arranged between the bleachable layer and the photochromic layer.

20. The photosensitive layer stack according to claim 3 further comprising a third interface layer being arranged below the photochromic layer.

21. A photosensitive layer stack for multiple exposure lithography comprising:
a bleachable layer deposited on a resist film with an exposure threshold, the bleachable layer being initially absorptive and switching in at least one selected area to transmissive under irradiation above a first exposure dose; and
a photochromic layer, the photochromic layer being initially transmissive and switching in the at least one selected area to absorptive under irradiation, wherein each of the selected areas is defined by a photomask.

22. The photosensitive layer stack according to claim 21, wherein the selected area corresponds to a pattern on the photomask.

23. The photosensitive layer stack according to claim 21, wherein each of the selected area possesses a size that differs from a corresponding structural element of a pattern on the photomask.

24. The photosensitive layer stack according to claim 23, wherein the size of selected area is greater than the corresponding structural element.

25. The photosensitive layer stack according to claim 23, wherein the size of selected area is smaller than the corresponding structural element.

26. The photosensitive layer stack according to claim 21, wherein the photochromic layer switches from transmissive to absorptive under irradiation after a further treatment.

27. The photosensitive layer stack according to claim 26, wherein the further treatment comprises performing at least one of a further irradiation, a thermal cycle, a wait cycle, or a chemical interaction with a gas or a liquid.

28. The photosensitive layer stack according to claim 27, wherein the size of the selected area is determined by the further treatment.

29. The photosensitive layer stack according to claim 21, wherein the further treatment comprises performing a further irradiation, and the size of the selected area is determined by an exposure dose of the further irradiation.

30. A method for multiple exposure lithography, the method comprising:
providing a resist film layer;
providing a bleachable layer;
providing a photochromic layer;
performing a first exposure using a first pattern, the first exposure comprising:
irradiating the photochromic layer to switch the photochromic layer from transmissive to absorptive,
irradiating the bleachable layer to switch the bleachable layer from absorptive to transmissive, and
irradiating the resist film layer in a first area corresponding to the first pattern; and
performing a second exposure using a second pattern, the second exposure comprising:
irradiating the photochromic layer to switch the photochromic layer from transmissive to absorptive,
irradiating the bleachable layer to switch the bleachable layer from absorptive to transmissive, and
irradiating the resist film layer in a second area corresponding to the second pattern.

31. The method according to claim 30, wherein the first pattern and the second pattern are arranged on different areas of a single photomask.

32. The method according to claim 30, wherein the first pattern is arranged on a first photomask and the second pattern is arranged on a second photomask, the first photomask being replaced by the second photomask after performing the first exposure.

33. The method according to claim 30, wherein the photochromic layer is arranged above the bleachable layer.

34. The method according to claim 30, wherein the photochromic layer is arranged below the bleachable layer.

35. The method according to claim 30, wherein the bleachable layer switches from absorptive to transmissive under irradiation with electromagnetic radiation having a wavelength in the UV-range above a first irradiation dose.

36. The method according to claim 30, wherein the photochromic layer switches from transmissive to absorptive under irradiation after a further treatment.

37. The method according to claim 36, wherein the further treatment includes performing at least one of a further irradiation, a thermal cycle, a wait cycle, or a chemical interaction with a gas or a liquid.

38. The method according to claim 37, wherein the photochromic layer switches from transmissive to absorptive under irradiation after performing a further irradiation having a wavelength being different to the wavelength of the irradiation and being insensitive to the resist film layer.

39. The method according to claim 30 further comprising performing a third exposure using a third pattern, the third exposure including:
irradiating the photochromic layer to switch the photochromic layer from transmissive to absorptive,
irradiating the bleachable layer so as to switch from absorptive to transmissive, and
irradiating the resist film layer in a third area corresponding to the third pattern.

40. A method for multiple exposure lithography, the method comprising:
providing a resist film layer;
providing a bleachable layer being initially absorptive;
providing a photochromic layer being initially transmissive;
performing a first exposure using a pattern on a first photomask, the first exposure comprising irradiating the photochromic layer in a first area;
performing a treatment of the photochromic layer to switch the photochromic layer from transmissive to absorptive at least in the first area;
performing a second exposure comprising:
irradiating the bleachable layer to switch the bleachable layer from absorptive to transmissive, and
irradiating the resist film layer in a second area.

41. The method according to claim 40 wherein the treatment is selected from the group consisting of performing a further irradiation, performing a thermal cycle, performing a wait cycle, or performing a chemical interaction with a gas or a liquid.

42. The method according to claim 40 wherein switching the photochromic layer from transmissive to absorptive is stable at least until the second exposure is completed.

43. The method according to claim 40 wherein the treatment enlarges the first area in which the photochromic layer switches from transmissive to absorptive.

44. The method according to claim 40 wherein the second exposure utilizes a second photomask.

45. The method according to claim 40, wherein the second exposure utilizes a flood exposure.

46. A lithographic system for multiple exposure lithography, the system comprising:
a lithographic projection apparatus including a substrate holder and a photomask; and
a substrate being arranged on the substrate holder, the substrate including:
a bleachable layer deposited on a resist film, the bleachable layer being initially absorptive and switching in at least one selected area to transmissive under irradiation above a first exposure dose, and
a photochromic layer, the photochromic layer being initially transmissive and switching in the at least one selected area to absorptive under irradiation,
wherein exposure of the resist film in the selected area is determined by the photomask.
